(19) United States
(12) Patent Application Publication
(10) Pub. No.: US 2026/0219201 A1
(43) Pub. Date: Jul. 30, 2026

(54) DEFECT INSPECTION DEVICE, PROCESSING DEVICE, AND DEFECT INSPECTION METHOD

(71) Applicant: HITACHI HIGH-TECH CORPORATION, Minato-ku, Tokyo (JP)

(72) Inventors: Shogo IGUCHI, Tokyo (JP); Toshifumi HONDA, Tokyo (JP)

(21) Appl. No.: 19/147,463

(22) PCT Filed: Jan. 16, 2023
(86) PCT No.: PCT/JP2023/000924

§ 371 Date: Jul. 11, 2025

(51) Int. Cl. G01N 21/88; G01N 21/95

(52) U.S. Cl. CPC G01N 21/8851; G01N 21/9501; G01N 2021/8864; G01N 2021/8877; G01N 2021/8883

(57) ABSTRACT

Performed are applying illumination light to a sample and detecting light from the sample by a first method with use of a first inspection system, applying illumination light to the sample and detecting light from the sample by a second method with use of a second inspection system, comparing each of the detection signals of the first inspection system and the detection signals of the second inspection system with a high sensitivity threshold defined for detection including misinformation, to detect defect candidates, checking for comparison between coordinates of the defect candidates detected by the first inspection system and coordinates of the defect candidates detected by the second inspection system, and grouping the defect candidates into a first group including the defect candidates detected by only the first inspection system, a second group including the defect candidates detected by only the second inspection system, and a third group including the defect candidates detected by both the first inspection system and the second inspection system, and classifying the defect candidates into at least one class in accordance with defect types for each of the first group, the second group, and the third group on the basis of a classification algorithm individually set for each of the groups.

### TECHNICAL FIELD

The present invention relates to a defect inspection device, a processing device, and a defect inspection method for inspecting a defect of a sample such as a semiconductor silicon wafer.

### BACKGROUND ART

As a defect inspection device for inspecting defects of a semiconductor silicon wafer or other samples, there is a known device which combines inspection using scattered light and inspection using differential interference (DIC) to achieve classification of defects (e.g., Patent Document 1).

### PRIOR ART DOCUMENT

### Patent Document

Patent Document 1: U.S. Pat. No. 7,728,969

### SUMMARY OF THE INVENTION

### Problems to be Solved by the Invention

Inspection which combines inspection techniques using different methods, such as scattered light inspection and differential interference inspection, is required to more accurately classify defects on the basis of features of defects detected by each of the inspection techniques. However, defects are not necessarily detectable by both of the inspection techniques. It is hence difficult to classify all of detected defects by a uniform method. Moreover, while detailed classification is achievable in association with an increase in features acquirable for defects by combining a plurality of inspection techniques adopting different detection methods, erroneous classification may easily be caused by an increase in the number of classes of the classification.

An object of the present invention is to provide a defect inspection device, a processing device, and a defect inspection method capable of improving classification accuracy of defects even with use of a combination of a plurality of inspection techniques adopting different methods.

### Means for Solving the Problems

For achieving the abovementioned object, the present invention provides a defect inspection device including a stage that moves while carrying a sample, a first inspection system that applies illumination light to the sample and detects light from the sample by a first method, a second inspection system that applies illumination light to the sample and detects light from the sample by a second method different from the first method, and a signal processing device that processes detection signals output from the first inspection system and the second inspection system. The signal processing device compares each of the detection signals of the first inspection system and the detection signals of the second inspection system with a high sensitivity threshold defined for detection including misinformation, to detect defect candidates, checks for comparison between coordinates of the defect candidates detected by the first inspection system and coordinates of the defect candidates detected by the second inspection system, to group the defect candidates into a first group containing the defect candidates detected by only the first inspection system, a second group containing the defect candidates detected by only the second inspection system, and a third group containing the defect candidates detected by both the first inspection system and the second inspection system, and classifies the defect candidates into at least one class on the basis of a classification algorithm individually set for each of the first group, the second group, and the third group. Thresholding, rule-type classification, teaching classification, or the like is employed for this classification algorithm.

### Advantages of the Invention

According to the present invention, improvement of classification accuracy of defects is achievable even with use of a combination of a plurality of inspection techniques adopting different methods.

### BRIEF DESCRIPTION OF THE DRAWINGS

FIG. 1 is a schematic diagram illustrating a defect inspection device according to an embodiment of the present invention.

FIG. 2 is a diagram illustrating an example of a scanning trajectory on a sample surface.

FIG. 3 is a schematic diagram illustrating one configuration example of an attenuator.

FIG. 4 is a schematic diagram illustrating one configuration example of an oblique incidence illumination optical system included in a scattered light inspection illumination section.

FIG. 5 is a schematic diagram illustrating one configuration example of a vertical incidence illumination optical system included in the scattered light inspection illumination section.

FIG. 6 is a schematic diagram illustrating a positional relation between some of sensors for detecting scattered light of oblique incidence illumination, as viewed in a direction perpendicular to the sample surface.

FIG. 7 is a schematic diagram illustrating a positional relation between regions for detecting scattered light and reflection light (apertures), as viewed in a direction perpendicular to the sample surface.

FIG. 8 is a schematic diagram illustrating one configuration example of a second inspection system (differential interference inspection illumination section and detection section).

FIG. 9 is a diagram illustrating a flow of a series of processes for classifying defects detected by each of scattered light inspection and differential interference inspection according to defect types in the present embodiment of the invention.

FIG. 10 is an explanatory diagram of a high sensitivity threshold and a low sensitivity threshold used for the series of processes for classifying defects detected by each of scattered light inspection and differential interference inspection according to defect types in the present embodiment of the invention.

FIG. 11 is a Venn diagram illustrating a relation between defect candidates grouped into a first group, a second group, and a third group.

FIG. 12 is a schematic diagram illustrating a concept of processes ranging from class classification (fine classification) of defect candidates contained in respective groups grouped by inspection methods to output.

FIG. 13 is a diagram illustrating an example of a block diagram of classification into the first group, the second group, and the third group.

FIG. 14 is a diagram illustrating an example of a GUI for setting a rule-type classification logic for each of the groups presented in FIG. 13.

FIG. 15 is a diagram illustrating an example of a GUI for setting classes for each of the groups presented in FIG. 13.

FIG. 16 is a diagram illustrating reduction of the number of classes achieved by setting a class of a defect type of others in comparison with the number of classes in FIG. 12.

FIG. 17 is a conceptual diagram illustrating an example of machine learning applied to class classification for each of the groups instead of the rule-type classification logic.

FIG. 18 is an explanatory diagram of classification accuracy.

FIG. 19 is an explanatory diagram of an example which provides a classification result of a different group as teaching data to compensate for insufficiency of teaching data in class classification for each of the groups.

FIG. 20 is a diagram illustrating one example of a GUI which displays a defect type map obtained by defect classification and detailed data obtained for each of defect candidates.

FIG. 21 is an explanatory diagram illustrating an idea for increasing the number of pieces of teaching data by offline reinspection under different conditions.

### MODE FOR CARRYING OUT THE INVENTION

An embodiment according to the present invention will hereinafter be described with reference to the drawings.

### —Defect Inspection Device—

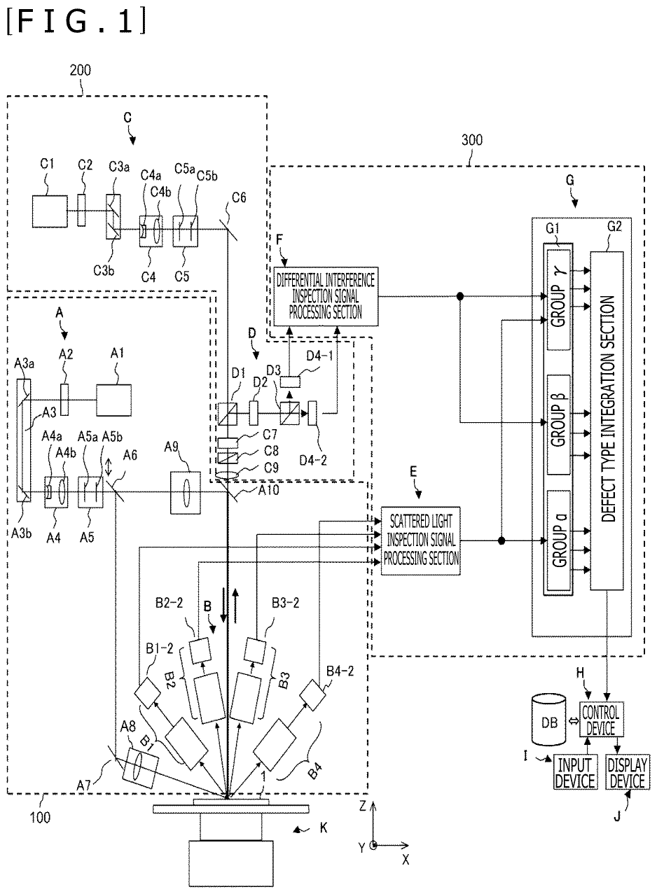

FIG. 1 is a schematic diagram illustrating a defect inspection device according to an embodiment of the present invention. The defect inspection device to which the present invention is applied typically includes a plurality of types of inspection systems using different defect detection methods. A defect inspection device illustrated in FIG. 1 by way of example includes a stage K which moves while carrying a sample 1 such as a semiconductor silicon wafer, a first inspection system 100 which applies illumination light to the sample 1 and detects light from the sample 1 by a first method, a second inspection system 200 which applies illumination light to the sample 1 and detects light from the sample 1 by a second method different from the first method, and a signal processing device 300 which processes detection signals output from the first inspection system 100 and the second inspection system 200. The first inspection system 100 included in the defect inspection device of the present embodiment is a scattered light inspection system which applies illumination light to the sample 1 and detects light scattered on the sample 1. The second inspection system 200 is a differential interference inspection system (DIC) which applies rays of spectrally dispersed illumination light to the sample 1 and detects rays of light reflected on the sample 1 and synthesized into interference light. While presented in the present embodiment by way of example is the defect inspection device which includes two types of inspection systems using different defect detection methods as described above, the present invention is also applicable to a defect inspection device which includes three or more types of inspection systems.

The defect inspection device according to the present embodiment includes a scattered light inspection illumination section A, a detection section B, a differential interference inspection illumination section C, a detection section D, a scattered light signal processing section E, a differential interference signal processing section F, a defect inspection section G, a control device H, an input device I, a display device J, and the stage K. The scattered light inspection illumination section A and the detection section B for the scattered light inspection illumination section A constitute the first inspection system 100 described above. The differential interference inspection illumination section C and the detection section D for the differential interference inspection illumination section C constitute the second inspection system 200 described above. The scattered light signal processing section E, the differential interference signal processing section F, and the defect inspection section G constitute the signal processing device 300 described above.

Each of the signal processing device 300 and the control device H is a computer, and includes a ROM, a RAM, and other memories, and further includes a CPU, an FPGA, a timer, and the like. It is assumed in one example that the signal processing device 300 is constituted by a single computer combined with a main body of the defect inspection device (stage K, first inspection system 100, second inspection system 200, etc.) into a unit. However, the signal processing device 300 in different examples may be constituted by a plurality of computers connected via a network. In this case, one of the plurality of computers may be a server. This server can be included in constituent elements of the defect inspection device or the signal processing device. For example, the following configuration is adoptable. A computer attached to the main body of the defect inspection device (a mechanical part executing inspection for the first inspection system 100, the second inspection system 200, the stage K, and the like) acquires defect detection signals from the main body, processes the detection signals as necessary, and transmits the processed detection signals to the server. The server executes processes such as defect classification for the received detection signals.

The scattered light signal processing section E, the differential interference signal processing section F, and the defect inspection section G of the signal processing device 300 may be implemented either virtually by software, or by hardware such as electronic circuits. A part (particularly, upstream processes) of the scattered light signal processing section E and other sections noted here may include an FPGA or a DSP. Some or all of the functions of the scattered light signal processing section E and other sections noted here may be executed by a server. Moreover, the signal processing device 300 and the control device H may be implemented by one computer.

The scattered light inspection illumination section A includes a laser light source A1, an attenuator A2, an emission light adjustment section A3, a beam expander A4, a polarization control section A5, mirrors A6 and A7, a collection lens A8, a collection lens A9, and a dichroic mirror A10.

Laser beams emitted from the laser light source A1 are adjusted to beams each having a desired beam intensity by the function of the attenuator A2, a desired beam position and a desired beam traveling direction by the function of the emission light adjustment section A3, a desired beam radius by the function of the beam expander A4, and a desired polarization state by the function of the polarization control section A5. In a case of oblique incidence illumination, these beams are narrowed by the collection lens A8 and applied to an inspection target region of the sample 1 by use of the mirrors A6 and A7.

An incidence angle of the illumination light with respect to a surface of the sample 1 (hereinafter abbreviated as a sample surface) is determined on the basis of positions and angles of reflection mirrors A3a and A4b of the emission light adjustment section A3 disposed in an optical path of the scattered light inspection illumination section A. The incidence angle of the illumination light is set to an angle appropriate for detection of small defects. Scattered light from small bumps and dents of the sample surface (called haze) and light from patterns on the sample, both recognized as noise for scattered light coming from small foreign matter on the sample surface, are more weakened as the illumination incidence angle becomes larger, i.e., an illumination elevation angle (an angle formed by the sample surface and the illumination optical axis) becomes smaller. Accordingly, a larger illumination incidence angle is suited for detection of small defects. It is hence preferable that the incidence angle of the illumination light be set to 75 degrees or more (elevation angle: 15 degrees or smaller) in a case where scattered light from small bumps and dents on the sample surface disturbs detection of small defects. Meanwhile, for oblique incidence illumination, an absolute quantity of scattered light from small foreign matter increases as the illumination incidence angle becomes smaller. It is hence preferable that the incidence angle of the illumination light be set in a range of 60 to 75 degrees (elevation angle: 15 to 30 degrees) in a case where detection of small defects is difficult due to a deficiency of the scattered light quantity from defects. Moreover, in the case of illumination for scattered light inspection, scattered light from defects on the sample surface increases by adoption of P-polarized light for polarization of illumination under polarization control using a half wavelength plate A5a and a quarter wavelength plate A5b included in the polarization control section A5 of the scattered light inspection illumination section A, in comparison with other types of polarization. Furthermore, in a case where scattered light from small bumps and dents on the sample surface disturbs detection of small defects, scattered light from small bumps and dents on the sample surface decreases by adoption of S-polarized light for polarization of illumination in comparison with other types of polarization.

In addition, when the mirror A6 is removed from the optical path of the scattered light inspection illumination section A as necessary, the illumination path changes as illustrated in FIG. 1. In this case, the illumination light narrowed by the collection lens A9 is reflected on the dichroic mirror A10 and applied to the sample surface in a substantially vertical direction (vertical illumination). The dichroic mirror is designed to reflect light for scattered light inspection and transmit light for differential interference inspection. Vertical illumination which causes light to enter the sample surface in a substantially vertical direction is suited for acquisition of scattered light from depressed defects on the sample surface (polishing scratches or crystal defects in crystal materials).

A laser light source employed for the laser light source A1 is of such a type which oscillates ultraviolet or vacuum ultraviolet laser beams having a short wavelength (wavelength: 355 nm or shorter) as a wavelength difficult to infiltrate into the sample and achieves high-power output of 2 W or higher for detecting small defects in the vicinity of the sample surface. Employed for detecting defects inside the sample is a laser light source of such a type which oscillates visible or infrared laser beams having a wavelength easy to infiltrate into the sample.

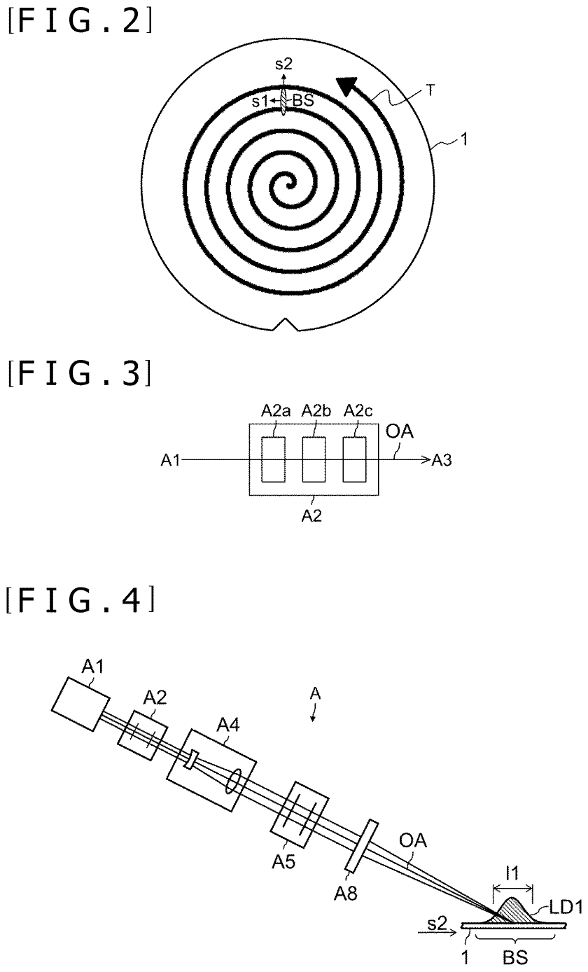

As illustrated in FIG. 3, the attenuator A2 which includes a combination of a polarization plate and a wavelength plate, for example, is provided to reduce a laser light intensity.

The emission light adjustment section A3 includes a plurality of reflection mirrors. While described here is the configuration of the emission light adjustment section A3 including the two reflection mirrors A3a and A3b, the emission light adjustment section A3 is not required to have the configuration of this example and may have a configuration including three or more reflection mirrors as necessary. It is assumed here that incident light entering the reflection mirrors travels in a +X direction in a three-dimensional rectangular coordinate system (XYZ coordinates) temporarily defined. The first reflection mirror A3a is disposed in such a position as to polarize the incident light into light in a +Y direction (entrance and reflection in the X-Y plane), while the second reflection mirror A3b is disposed in such a position as to polarize the light reflected on the first reflection mirror into light in a +Z direction (entrance and reflection in the Y-Z plane). Each of the reflection mirrors adjusts a position and a traveling direction (angle) of light emitted from the emission adjustment section A3 by parallel movement and tilt angle adjustment. As described above, the entrance and reflection surface (X-Y surface) of the first reflection mirror and the entrance and reflection surface (Y-Z surface) of the second reflection mirror are so disposed as to cross each other at right angles. In this manner, adjustment of the position and the angle in the X-Z plane and adjustment of the position and the angle in the Y-Z plane for the light emitted from the emission light adjustment section A3 (traveling in the +Z direction) can be achieved independently of each other.

The beam expander A4 including two or more lens groups has a function of expanding a diameter of parallel luminous flux having entered. For example, a Galilean beam expander which includes a combination of a concave lens and a convex lens is employed. The beam expander A4 is provided on a translational stage having two or more axes, and is capable of achieving positional adjustment for alignment between a predetermined beam position and a center. Moreover, the beam expander A4 has a function of adjusting a tilt angle of the entire beam expander A4 for alignment between an optical axis of the beam expander A4 and a predetermined beam optical axis. A magnification rate of the luminous flux diameter is controllable by adjusting intervals of the lenses (zoom mechanism). In a case where light entering the beam expander A4 is not parallel, magnification of the luminous flux diameter and collimation (conversion of luminous flux into quasi-parallel light) are simultaneously carried out by adjusting the intervals of the lenses. Collimation of the luminous flux may be achieved by a collimating lens provided upstream of the beam expander A4 and operating independently of the beam expander A4.

The polarization control section A5 including the half wavelength plate A5a and the quarter wavelength plate A5b controls a polarization state of illumination light such that the polarization state becomes any desired polarization state.

Similarly to the emission light adjustment section A3, each of the mirrors A6 and A7 is available for adjustment of the position and the angle of oblique incident light.

The angle and the position of the collection lens A8 are adjustable for alignment between optical axes of the collection lens A8 and incident light.

Rays of scattered light scattered in various directions from an illumination spot formed on the sample surface by the scattered light inspection illumination section A enter a plurality of scattered light detection optical systems B1 through B4 of the detection section B, and are detected by scattered light sensors B1-2, B2-2, B3-2, and B4-2 via the foregoing scattered light detection optical systems B1 through B4. Detection signals (scatter signal intensities) output from the scattered light sensors B1-2, B2-2, B3-2, and B4-2 are input to the scattered light signal processing section E.

On the basis of datasets of the detection signals input from the scattered light sensors B1-2, B2-2, B3-2, and B4-2 along with a correlation with coordinates on the sample surface, the scattered light signal processing section E calculates an integrated signal of these datasets. The scattered light signal processing section E compares a signal intensity of the integrated signal with a predetermined threshold (high sensitivity threshold), and determines whether the signal intensity exceeds the predetermined threshold. The high sensitivity threshold is a value set for detection of a large number of defect candidates, including misinformation, and is set to a value lower than a low sensitivity threshold set for detecting true defects. The scattered light signal processing section E outputs the integrated signal exceeding the high sensitivity threshold and the datasets of the detection signals associated with this integration signal, as a signal of a defect candidate.

Similarly to the scattered light inspection illumination section A, the differential interference inspection illumination section C used for differential interference detection includes a laser light source C1, an attenuator C2, an emission light adjustment section C3, a beam expander C4, and a polarization control section C5. After reflected on a mirror C6, illumination light is converted into circularly polarized light by a quarter wavelength plate C7, and separated into two rays of linearly polarized light having oscillation surfaces crossing each other at right angles, such as S-polarized light and P-polarized light, by a Nomarski prism C8. Thereafter, each ray of the separated light enters an objective lens C9 for differential interference inspection.

The objective lens C9 is mounted on a stage. A pupil position of the objective lens C9 is aligned with a separation position of the Nomarski prism C8. The two rays of linearly polarized light having passed through the objective lens C9 are applied to an inspection target region of the sample 1 in parallel, and each form an illumination spot. The two rays of linearly polarized light reflected on the sample surface are resynthesized into interference light in the same optical path by the Nomarski prism C8. After entering the detection section D via a beam splitter D1, this interference light is narrowed by an image forming lens D2, and separated into S-polarized light and P-polarized light by a polarization beam splitter D3. Thereafter, these rays of separated light are respectively detected by interference light sensors D4-1 and D4-2. A sensor available as the interference light sensor D4 may be a point sensor, an area sensor, or a multiline sensor, and may be a photomultiplier tube, a SiPM, a CMOS sensor, a CCD, or the like in view of sensor types, for example. An interference intensity of interference light changes according to a differential height (a height difference between two illumination spots formed on the sample 1 with deviation corresponding to a shear amount). Accordingly, the differential height can be measured by use of the differential interference signal processing section F which processes the interference intensity of interference light measured by the interference light sensors D4-1 and D4-2 and A/D-converted and correlated with coordinate data on the sample surface.

The differential interference signal processing section F first calculates the differential height on the basis of outputs from the interference light sensors D4-1 and D4-2, and deconvolutes the calculated differential height to calculate the height of the sample surface. Moreover, the differential interference signal processing section F compares at least either the differential height or the height of the sample surface thus calculated with a reference value set beforehand, and further compares a difference from the reference value with a predetermined threshold (high sensitivity threshold) to determine whether this difference exceeds the high sensitivity threshold. The high sensitivity threshold is a determination value set for detection of a large number of defect candidates, including misinformation, and is set to a value lower than a low sensitivity threshold set for detecting true defects. In a case where the difference exceeds the predetermined threshold, the differential interference signal processing section F outputs data of the corresponding differential height and the corresponding height of the sample surface, as a signal of a defect candidate, together with coordinates on the sample surface.

Outputs from the scattered light signal processing section E and the differential interference signal processing section F (feature data such as coordinates of defect candidates, the scattered light intensity, the differential height, and the height of the sample surface) are input to the defect inspection section G. A defect classification section G1 of the defect inspection section G checks for comparison between coordinates of defect candidates detected by the first inspection system 100 (output from the scattered light signal processing section E) and coordinates of defect candidates detected by the second inspection system 200 (output from the differential interference signal processing section F). In this manner, the defect candidates detected by the first inspection system 100 and the second inspection system 200 are initially grouped (roughly classified) into a group α of defect candidates detected only by the scattered light inspection, a group β of defect candidates detected by only the differential interference inspection, and a group γ of defect candidates detected by both the scattered light inspection and the differential interference inspection.

A defect type integration section G2 of the defect inspection section G further classifies (finely classifies) the defect candidates into a plurality of classes for each of the groups according to defect types on the basis of a classification algorithm individually set for each of the groups α, β, and γ. Thereafter, the defect inspection section G compares each of the defect candidates classified into the plurality of classes for each of the groups α, β, and γ with the low sensitivity threshold, and outputs defect inspection data from which misinformation has been filtered out, as a final output. At this time, the pieces of defect inspection data contained in different groups but classified into the same class are integrated and output as defect inspection data in an identical class. The low sensitivity threshold is a determination value provided for detecting true defects and set to a value higher than the high sensitivity threshold described above. This output may be stored in a database DB, or displayed on the display device J. Pieces of previous defect inspection data accumulated in the database DB are also available as teaching data for defect classification.

Note that the control device H executes control for the main body (stage K, first inspection system 100, second inspection system 200, etc.) of the defect inspection device during the inspection operation described above. Correlation between outputs from the first and second inspection systems 100 and 200 and coordinates on the sample surface is executed on the basis of control data output from the control device H. Input operations associated with inspection conditions, display on the display device J, and others are achieved by operation of the input device I.

### —Example of Scanning—

FIG. 2 is a diagram illustrating an example of a scanning trajectory on the sample surface. Explanation on an illuminance distribution shape (illumination spot BS) formed on the sample surface by the scattered light inspection illumination section A and the differential interference inspection illumination section C and on a sample scanning method will be made with reference to FIG. 2. It is assumed in FIG. 2 that the sample 1 is a circular semiconductor silicon wafer. The stage K includes a translation stage, a rotation stage, and a Z stage for sample surface height adjustment (none of these are illustrated). The illumination spot BS has an illumination intensity distribution which is long in one direction. It is assumed that a longitudinal direction of the illumination spot BS is S2 and that a direction substantially perpendicular to S2 is S1. The illumination spot BS is scanned in a circumferential direction of a circle around a center located at a rotation axis of the rotation stage (S1 direction) by rotational movement of the rotation stage, and simultaneously scanned in a translational direction of the translation stage (S2 direction) by translational movement of the translation stage. By scanning in the scanning direction S1, the sample 1 translationally moves in the S2 direction by a distance equal to or shorter than a length of the illumination spot BS in the longitudinal direction while the sample 1 rotates once. In this manner, the illumination spot BS moves on the sample surface while drawing a spiral trajectory T, and scanning for the entire surface of the sample 1 is thus achieved.

### —Configuration Example of Attenuator—

FIG. 3 is a schematic diagram illustrating one configuration example of the attenuator A2. The attenuator A2 is a unit for attenuating the light intensity of illumination light emitted from the laser light source A1, and has a combination of a first polarization plate A2a, a half wavelength plate A2b, and a second polarization plate A2c in a configuration presented by way of example according to the present embodiment. The half wavelength plate A2b is configured to be rotatable around the optical axis of the illumination light. Illumination light having entered the attenuator A2 is converted into linearly polarized light by the first polarization plate A2a, and then passes through the second polarization plate A2c in a polarization direction adjusted to a slow axis azimuth of the half wavelength plate A2b. The azimuth adjustment by the half wavelength plate A2b can attenuate the light intensity of the illumination light at a desired rate. In a case where the degree of linear polarization of the illumination light entering the attenuator A2 is sufficiently high, the first polarization plate A2a may be eliminated. Note that the attenuator A2 is not required to have the configuration illustrated in FIG. 3 by way of example, and may include an ND filter having a gradation concentration distribution. In this case, the attenuator A2 may be configured to control an attenuation effect by a combination of a plurality of ND filters having different concentrations.

### —Configuration Example of Scattered Light Inspection Illumination Section—

FIGS. 4 and 5 are schematic diagrams of one configuration example of an oblique incidence illumination optical system of the scattered light inspection illumination section A. Each of FIGS. 4 and 5 illustrates a positional relation between an optical axis of illumination light obliquely guided to the sample surface by the scattered light inspection illumination section A and an illumination intensity distribution shape. FIG. 4 schematically illustrates a cross section of the sample 1 taken along an incidence plane of the illumination light entering the sample 1. FIG. 5 schematically illustrates a cross section of the sample 1 taken along a plane that is orthogonal to the incidence plane of the illumination light entering the sample 1 and that contains a normal line of the sample surface. The incidence plane refers to a plane containing an optical axis OA of the illumination light entering the sample 1 and the normal line of the sample surface. Note that each of FIGS. 4 and 5 illustrates a part extracted from the scattered light inspection illumination section A, and does not illustrate the emission light adjustment section A3 and the mirrors A6 and A7, for example.

In a case where the mirror A6 is inserted into the optical path, the illumination light emitted from the laser light source A1 is reflected on the mirror A7 and collected by the collection lens A8, and then obliquely enters the sample 1. In this manner, the scattered light inspection illumination section A is configured to introduce illumination light into the sample 1 obliquely with respect to the normal line of the sample surface. According to this oblique incidence illumination, the light intensity, a luminous flux diameter, and polarization are adjusted by the attenuator A2, the beam expander A4, and the polarization control section A5, respectively, to equalize an illumination intensity distribution within the incidence plane. As indicated by an illumination intensity distribution (illumination profile) LD1 illustrated in FIG. 4, an illumination spot formed on the sample 1 has a Gaussian light intensity distribution in the s2 direction. A length of a beam width 11 defined at 13.5% of a peak is approximately in a range of 25 μm to 4 mm, for example.

As indicated by an illumination intensity distribution (illumination profile) LD2 illustrated in FIG. 5, the illumination spot has a light intensity distribution where the intensity is lower in the periphery of the optical axis OA than at the center within the plane orthogonal to the incidence plane and the sample surface. Specifically, the illumination spot has a Gaussian distribution reflecting the intensity distribution of light entering the collection lens A9, or an intensity distribution similar to a Bessel function of the first kind of an order 1 or a sinc function reflecting an aperture shape of the collection lens A9. A length 12 of the illumination intensity distribution within the plane orthogonal to the incidence plane and the sample surface is set to a length shorter than the beam width 11 illustrated in FIG. 4, such as in a range of approximately 1.0 to 20 μm, so as to reduce haze generated from the sample surface. The length 12 of the illumination intensity distribution here is a length of a region having an illumination intensity of 13.5% or more of the maximum illumination intensity within the plane orthogonal to the incidence plane and the sample surface.

### —Configuration Example of Scattered Light Detection Section—

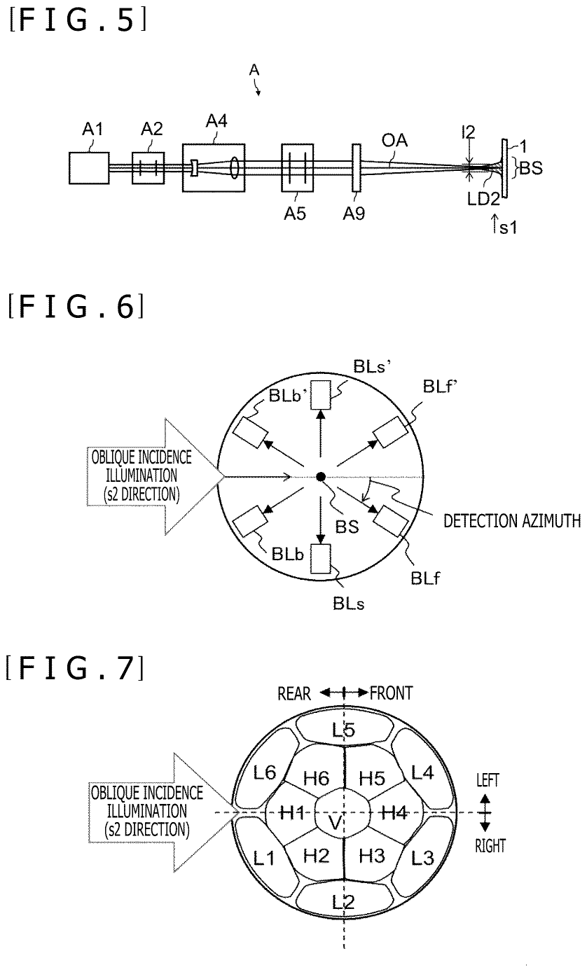

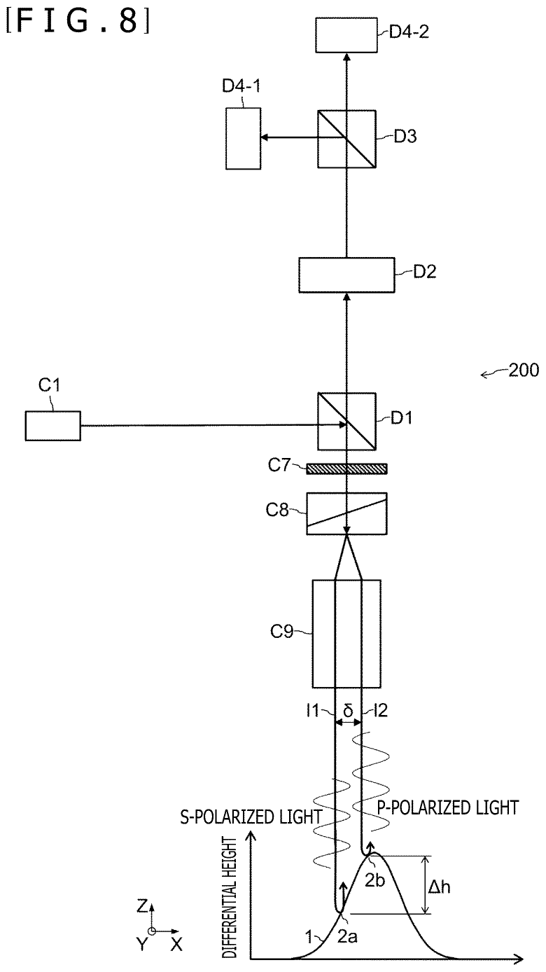

FIG. 6 is a schematic diagram illustrating a positional relation between some of sensors for detecting scattered light of oblique incidence illumination, as viewed in a direction perpendicular to the sample surface. FIG. 7 is a schematic diagram illustrating a positional relation between regions for detecting scattered light and reflection light (apertures), as viewed in a direction perpendicular to the sample surface.

A plurality of detection sections are provided as the detection section B of the first inspection system 100 to detect rays of scattered light emitted in a plurality of directions from the illumination spot BS. While the first inspection system 100 includes detection sections disposed at a low angle and detection sections disposed at a high angle, FIG. 6 is a plan diagram illustrating arrangement of low angle detection sections BL. An angle formed by a traveling direction of oblique incidence illumination and a detection direction within a plane parallel to the sample surface is defined as a detection azimuth. The low angle detection sections BL in FIG. 6 include a low angle front detection section BLf, a low angle side detection section BLs, and a low angle rear detection section BLb, and also a low angle front detection section BLf′, a low angle side detection section BLs′, and a low angle rear detection section BLb′ located at symmetrical positions of the foregoing detection sections with respect to the illumination incidence plane. For example, the low angle front detection section BLf is disposed at a detection azimuth of 0 to 60 degrees, the low angle side detection section BLs is disposed at a detection azimuth angle of 60 to 120 degrees, and the low angle rear detection section BLb is disposed at a detection azimuth angle of 120 to 180 degrees.

FIG. 7 is a diagram illustrating regions (apertures) where the detection section B for scattered light and the detection section D for interference light capture scattered light and reflection light, respectively, as viewed from above, and corresponds to arrangement of respective objective lenses of the scattered light detection optical systems B1 through B4 and the like. It is assumed in the following description that a traveling direction of incidence light with respect to the illumination spot BS on the sample surface (the right direction in FIG. 7) as viewed from above is the front and that the opposite direction (the left direction in FIG. 7) is the rear, on the basis of a reference corresponding to an incidence direction of oblique incidence illumination into the sample 1. Accordingly, the lower side and the upper side with respect to the illumination spot BS in this figure correspond to the right side and the left side, respectively.

The respective objective lenses of the scattered light detection optical systems B1 through B4 are disposed along a semispherical surface of an upper half of a sphere (celestial sphere) around a center located at the illumination spot BS with respect to the sample 1. This semispherical surface is divided into a total of 13 regions including regions L1 through L6, H1 through H6, and V, and the scattered light detection optical systems B1 through B4 capture and collect rays of scattered light in the corresponding regions.

The region V is a region overlapping with the zenith and is located right above the illumination spot BS formed on the sample surface.

The regions L1 through L6 are regions formed by equal dividing of an annular area surrounding the circumference of the illumination spot BS at low angles through 360 degrees, and arranged in an order of L1, L2, L3, L4, L5, and L6 anticlockwise in the incidence direction of the oblique incidence illumination as viewed from above. Among the foregoing regions L1 through L6, the regions L1 through L3 are located on the right side of the illumination spot BS. In this case, with respect to the illumination spot BS, the region L1 is located on the right rear, the region L2 is located on the right side, and the region L3 is located on the right front. The regions L4 through L6 are located on the left side of the illumination spot BS, In this case, with respect to the illumination spot BS, the region L4 is located on the left front, the region L5 is located on the left side, and the region L6 is located on the left rear.

The remaining regions H1 through H6 are regions formed by equal dividing of an annular area surrounding the circumference of the illumination spot BS at high angles (between the regions L1 through L6 and the region V) through 360 degrees, and arranged in an order of H1, H2, H3, H4, H5, and H6 anticlockwise in the incidence direction of the oblique incidence illumination as viewed from above. The positions of the regions H1 through H6 for high angles are shifted from the positions of the regions L1 through L6 for low angles by 30 degrees as viewed from above. Among the regions H1 through H6, the region H1 and the region H4 are located on the rear and front, respectively, with respect to the illumination spot BS. The regions H2 and H3 are located on the right side of the illumination spot BS. In this case, with respect to the illumination spot BS, the region H2 is located on the right rear, and the region H3 is located on the right front. The regions H5 and H6 are located on the left side of the illumination spot BS, In this case, with respect to the illumination spot BS, the region H5 is located on the left front, and the region H6 is located on the left rear.

In FIG. 1, each ray of the scattered light having entered the scattered light detection optical systems Bn (n=1, 2, and others) is collected and guided to a corresponding sensor Bn−2. As apparent from comparison between FIGS. 1 and 7, for example, the scattered light detection optical system B1 in FIG. 1 is an example of an optical system which captures scattered light in the region L6 in FIG. 7, the scattered light detection optical system B2 in FIG. 1 is an example of an optical system which captures scattered light in the region H6 in FIG. 7, the scattered light detection optical system B3 in FIG. 1 is an example of an optical system which captures scattered light in the region H5 in FIG. 7, and the scattered light detection optical system B4 in FIG. 1 is an example of an optical system which captures scattered light in the region L4 in FIG. 7. Reflection light of the illumination light for differential interference detection by the second inspection system 200 is captured in the region V in FIG. 7.

### —Second Inspection System—

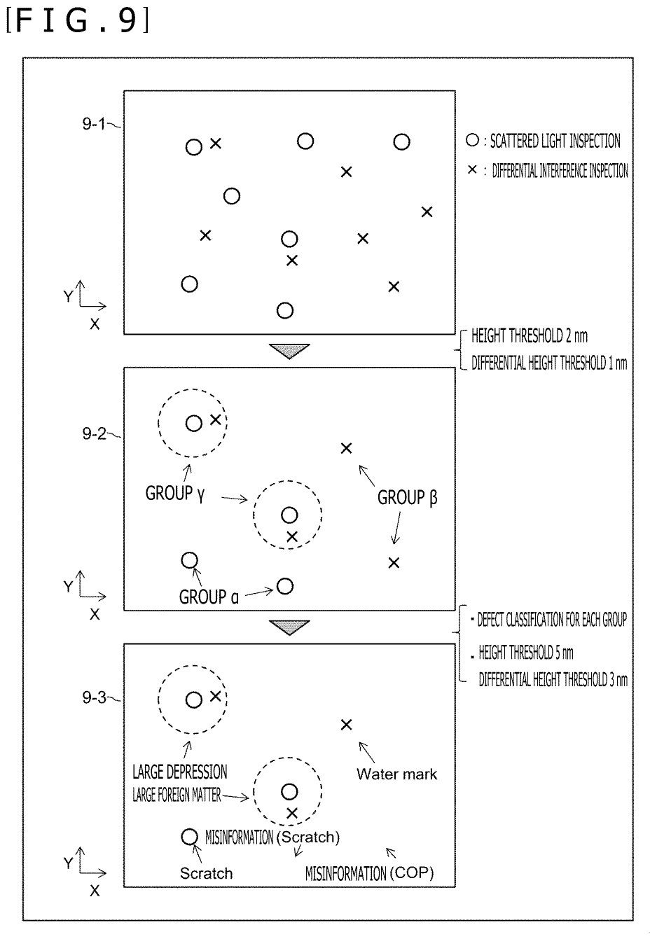

FIG. 8 is a schematic diagram of one configuration example of the second inspection system 200, i.e., the differential interference inspection illumination section C and the detection section D. The attenuator C2, the emission light adjustment section C3, the beam expander C4, the polarization control section C5, the mirror C6, and the like are not illustrated in FIG. 8.

The second inspection system 200 includes the laser light source C1, the beam splitter D1, the quarter wavelength plate C7, the Nomarski prism C8, the objective lens C9, the image forming lens D2, the polarization beam splitter D3, and the interference light sensors (photoelectric conversion elements) D4-1 and D4-2. Each of the differential interference inspection illumination section C and the detection section D for the differential interference inspection illumination section C is provided for detecting differential interference contrast to calculate the height of the sample surface, and collects rays of reflection light of two polarization illumination spots from the sample surface to form an image of interference light.

Emission light of the laser light source C1 has a wavelength different from that of the emission light of the laser light source A1. The emission light of the laser light source C1 is guided to the beam splitter D1 as linearly polarized light. Light released from the beam splitter D1 enters the quarter wavelength plate C7. The quarter wavelength plate C7 is disposed in such a position that a fast axis has an angle of 45 degrees with respect to an incidence polarization direction. In this case, the light released from the quarter wavelength plate C7 is converted into circularly polarized light.

The Nomarski prism C8 is made of an optical material having birefringence, and separates incidence light entering as circularly polarized light into two rays of linearly polarized light having oscillation surfaces crossing each other at right angles. The Nomarski prism C8 is movable in the X direction by a not-illustrated driving mechanism, and is capable of adjusting a phase difference between two separated beam spots to a difference of a desired size by adjusting its position in the X direction.

The objective lens C9 for differential interference contrast is mounted on a not-illustrated stage, and the position of the objective lens C9 is adjusted such that a pupil position is aligned with a separation position of the Nomarski prism C8. The two rays of light that have polarized components and are transmitted through the objective lens C9 travel substantially in parallel. Thereafter, beam spots in the two polarization directions are formed on the surface of the sample 1. When the two beam spots have a height difference, a phase difference is produced in polarization of rays of reflection light coming from the two beam spots. A positional shift amount between the two beam spots is referred to as a shear amount 5. In differential interference contrast measurement, a height difference between two beam spots (differential height) is measured on the basis of a phase change of two polarized components reflected on the sample surface. The rays of reflection light from the sample surface are collimated by the objective lens C9, and resynthesized into interference light in an identical optical path by the Nomarski prism C8. This interference light is guided to the image forming lens D2 via the beam splitter D1, narrowed by the image forming lens D2, and separated into S-polarized light and P-polarized light by the polarization beam splitter D3. Thereafter, the rays of separated light are respectively detected by the interference light sensors D4-1 and D4-2. The differential height is measured by measuring interference intensities of the rays of light detected by the interference light sensors D4-1 and D4-2. This differential height corresponds to a height difference between the two beam spots separated by the shear amount 5. Accordingly, a surface shape of the sample 1 can be acquired by accumulating differential heights obtained by scanning for each of the shear amounts 5.

### —Threshold Processing Before and After Defect Classification—

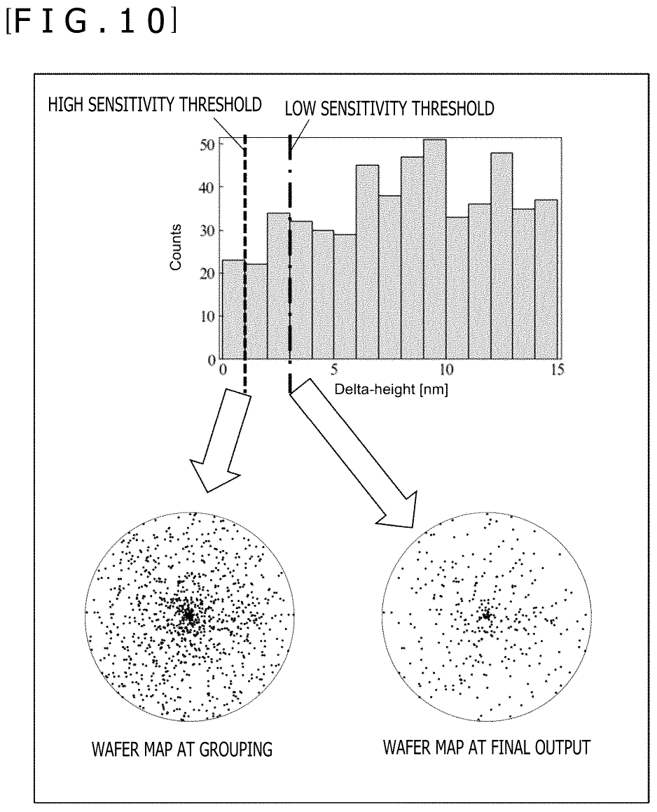

FIG. 9 is a diagram illustrating a flow of a series of processes for achieving defect classification according to defect types for defects detected by each of scattered light inspection and differential interference inspection in the present embodiment. FIG. 10 is an explanatory diagram of a high sensitivity threshold and a low sensitivity threshold used in this series of processes. The series of processes of the inspection method described with reference to FIG. 9 is executed by the signal processing device 300. Each of columns 9-1, 9-2, and 9-3 in FIG. 9 indicates the distribution of detection signals detected in an identical small region of the sample surface. Each round mark in the figure represents a detection signal detected by the first inspection system 100 using a scattered light inspection method, while each cross mark represents a detection signal detected by the second inspection system 200 using a differential interference inspection method.

For performing defect inspection of the sample surface, illumination light is first applied to the sample 1 to scan the sample surface and acquire detection signals while moving the stage K carrying the sample 1 (FIG. 2). At this time, the first inspection system 100 applies first illumination light to the sample 1 and detects scattered light from the sample 1 by using a first method (scattered light inspection method), and simultaneously the second inspection system 200 applies second illumination light to the sample 1 and detects interference light from the sample 1 by using a second method (differential interference inspection method) different from the first method. In this manner, detection signals generated by the first inspection system 100 and the second inspection system 200 are input to the processing device 300 as indicated in the column 9-1. Sufficiently accurate coordinates of the detection signals of the first inspection system 100 and the second inspection system 200 can be obtained by correction using a correction mechanism included in the defect inspection device (e.g., a mechanism which measures deviation between center coordinates of the sample 1 acquired by detection of the outer circumference of the sample 1 and the rotation center of the sample 1 to obtain a correction amount).

Subsequently, the detection signals of the first inspection system 100 and the detection signals of the second inspection system 200 indicated in the column 9-1 are each compared with a high sensitivity threshold for detection including misinformation, to detect defect candidates. In this step, noise is removed on the basis of comparison between the detection signals of the first inspection system 100 and the high sensitivity threshold by the scattered light signal processing section E, and comparison between the detection signals of the second inspection system 200 and the high sensitivity threshold by the differential interference signal processing section F. Each of the detection signals compared with the high sensitivity threshold by the scattered light signal processing section E is an integrated signal (light intensity) obtained by a plurality of the scattered light sensors Bn−2. Accordingly, the high sensitivity threshold compared with these detection signals is also a value of the light intensity. Each of the detection signals compared with the high sensitivity threshold by the differential interference signal processing section F is a differential height or a sample surface height calculated from the interference intensity of interference light. Accordingly, the high sensitivity threshold compared with these detection signals is also a value of a differential height or a sample surface height. As described above, the high sensitivity threshold for detecting a large number of signals including misinformation is set to a lower value than the low sensitivity threshold for filtering misinformation. As can be seen from thresholds set for a differential height applied to the differential interference signal processing section F as presented in FIG. 10 by way of example, the high sensitivity threshold (1 nm) is set to a value lower than the low sensitivity threshold (3 nm). As for the sample surface height, the low sensitivity threshold is set to approximately 5 nm, while the high sensitivity threshold is set to approximately 2 nm, for example. As indicated in the column 9-2, the number of defect candidates extracted after removal of a certain level of noise with use of these high sensitivity thresholds is smaller than the number of the defect candidates indicated in the column 9-1.

After the defect candidates are extracted with use of the high sensitivity thresholds, coordinates of the defect candidates detected by the first inspection system 100 and coordinates of the defect candidates detected by the second inspection system 200 are checked for comparison to carry out grouping (rough classification) into the group α (first group) including defect candidates detected by only the first inspection system 100, the group β (second group) including defect candidates detected by only the second inspection system 200, and the group γ (third group) including defect candidates detected by both the first inspection system 100 and the second inspection system 200. Specifically, in a case where a distance between the defect candidate detected by the first inspection system 100 and the defect candidate detected by the second inspection system 200 falls within a predetermined distance range, these defect candidates are classified into the group γ as identical defect candidates detected by both the inspection systems (column 9-2). The defect candidate detected by the first inspection system 100 but not coinciding with defect candidates detected by the second inspection system 200 within the predetermined distance range is classified into the group α. The defect candidate detected by the second inspection system 200 but not coinciding with defect candidates detected by the first inspection system 100 within the predetermined distance range is classified into the group β.

After the defect candidates are grouped into the groups α, β, and γ, the defect candidates are finely classified into at least one class (scratch, large depression, large foreign matter, and watermark in FIG. 9) according to defect types on the basis of a classification algorithm individually set for each of the groups α, β, and γ. Modes of fine classification will be described later. Thereafter, the defect candidates classified into at least one class for each group are compared with the low sensitivity threshold set to a value higher than the high sensitivity threshold to filter misinformation, and output as final inspection data. The column 9-3 indicates inspection data obtained after class classification and removal of misinformation. The defect candidates in the column 9-3 are reduced from the defect candidates in the column 9-2 by the number corresponding to the removal of misinformation. The defect candidates in the group γ have both features of the defect candidates included in the groups α and β. Accordingly, for example, the defect candidates whose features for both the scattered light inspection and the differential interference inspection are lower than the low sensitivity threshold are removed, while the defect candidates whose features for only either one of the scattered light inspection and the differential interference inspection are higher than or equal to the low sensitivity threshold are reserved as defect data. Thereafter, the features obtained by the scattered light inspection and the features obtained by the differential interference inspection are recorded while being correlated with coordinate data.

FIG. 10 illustrates a histogram which has a horizontal axis representing a differential height and a vertical axis representing the number of detected defects. A high sensitivity threshold and a low sensitivity threshold (>high sensitivity threshold) are set beforehand for each of the inspection methods. As indicated by comparison between wafer maps in the figure, it is obvious that the number of defect candidates extracted with use of the high sensitivity threshold is larger than the number of defects extracted with use of the low sensitivity threshold.

### —Grouping (Rough Classification)—

FIG. 11 is a Venn diagram indicating a relation between defect candidates grouped into the groups α, β, and γ. The defect candidates grouped into the groups α, β, and γ are different in type and number of features for each group. For example, defect candidates grouped into the group α have features a1, a2, and others (an integrated signal, a detection signal of the scattered light sensor B1-2, a detection signal of the scattered light sensor B2-2, etc.). Defect candidates grouped into the group β have features b1, b2, and others (a differential height, a sample surface height, a defect area, etc.). Defect candidates grouped into the group γ have both the features of the defective candidates grouped into the groups α and β. Values of the respective features are different for each of the defect candidates. Accordingly, each of the defect candidates is finely classified into any one of classes on the basis of algorithms and classes differently set for each of the groups α, β, and γ.

### —Class Classification (Fine Classification)—

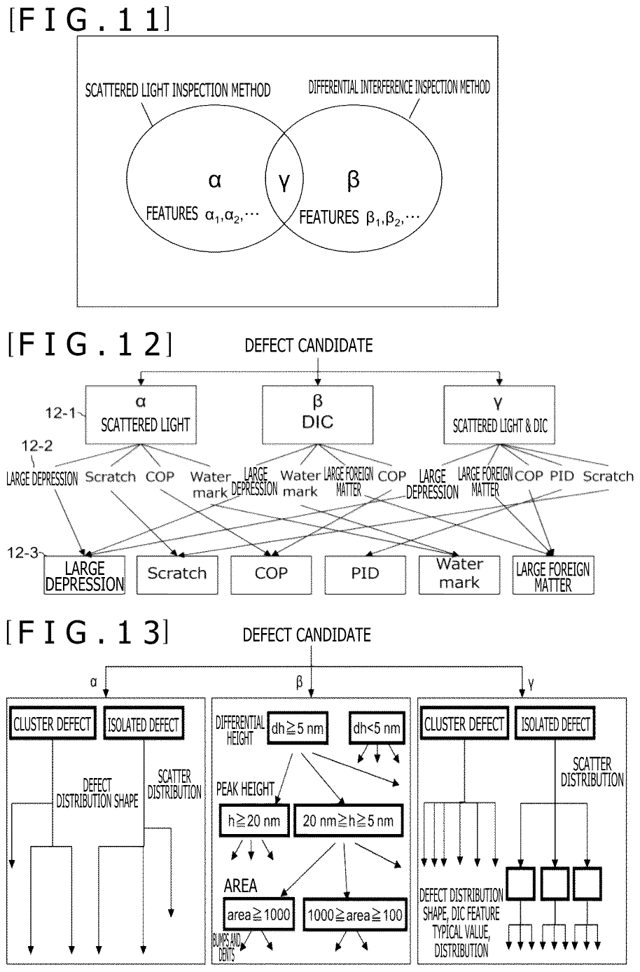

FIG. 12 is a schematic diagram illustrating a concept of processes ranging from class classification (fine classification) of defect candidates grouped into the groups α, β, and γ by the inspection methods to output. The defect type integration section G2 evaluates defect candidates 12-1 grouped into the groups α, β, and γ, by the classification algorithms set for each of the groups on the basis of features set for each of the groups, finely classifies each of the evaluated defect candidates 12-1 into any one of classes 12-2 set for each of the groups, and finally outputs the defect candidates as defect inspection data 12-3 which is a dataset of features and coordinates of the respective defect candidates. There is a possibility that some of the classes 12-2 included in the different groups overlap with each other. In this case, classification results of the classes 12-2 common to each of the groups are merged into the final defect inspection data 12-3 (large depression, scratch, COP, watermark, and large foreign matter in the example of FIG. 12).

### —Classification Algorithm—

FIG. 13 is a diagram illustrating an example of classification algorithms defined for each of the groups α, β, and γ. This figure illustrates a flow of classification of the defect candidates 12-1 in FIG. 12 into the classes 12-2 for each of the groups. For example, applicable to the group α which includes defect candidates having only features obtained by scattered light inspection is such a classification algorithm which classifies defects into cluster defects constituted by defect candidates in clusters and isolated defects around which other defect candidates are absent (in a predetermined distance range), then finely classifies the cluster defects by a defect distribution shape (e.g., a linear shape and a circular-arc shape), and finely classifies the isolated defects on the basis of a scattered light intensity distribution defined by respective detection signals of a plurality of the scattered light sensors Bn−2. Applicable to the group β which includes defect candidates having only features obtained by differential interference inspection is a rule-type classification method which sequentially classifies defect candidates by a differential height, a peak value (peak height) of heights obtained by accumulating differential heights, a defect area, and bumps and dents for fine classification. Applicable to the group γ which includes defect candidates having features obtained by both scattered light inspection and differential interference inspection is a rule-type classification method which first classifies defect candidates into cluster defects and isolated defects as in the group α, and sequentially classifies the respective classified defect candidates by a defect distribution shape, a scatter intensity distribution, and features obtained by differential interference inspection (differential height, peak height, etc.) for fine classification, for example.

### —Construction of Algorithm—

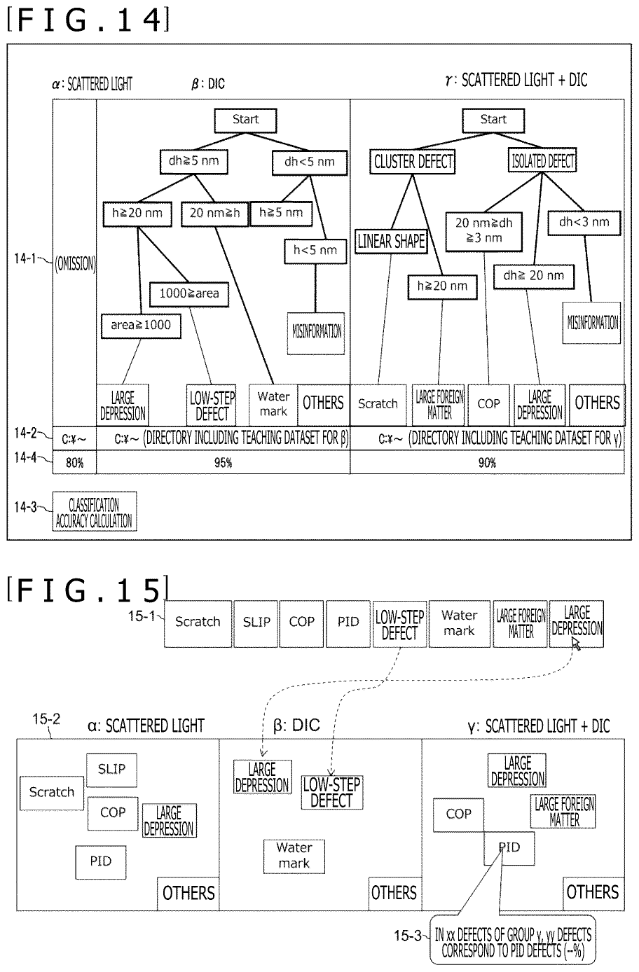

FIG. 14 is a diagram illustrating an example of a GUI for setting classification conditions of the rule-type classification method for each of the groups α, β, and γ illustrated in FIG. 13 (the group α is omitted in the figure). A rule-type classifier set in FIG. 14 is converted into a predetermined data format, recorded in a memory of the signal processing device 300, for example, and executed by the defect type integration section G2. It is possible that the classification conditions of the rule-type classifier in the GUI in FIG. 14 are set by a manual operation or machine learning in a classification condition column 14-1. In the case of the manual operation, for example, icons (not illustrated) of nodes (start, determination process, class, etc.) are dragged and dropped into the GUI in FIG. 14. Thereafter, determination conditions (e.g., for the group β, dh (differential height)≥5 nm, h (peak height)≥20 nm, area≥1000, etc.) are input to the node of the determination process, for example, and the respective nodes are connected by a link to construct a rule-type classifier.

As described above, pieces of inspection data of previous defect inspection are accumulated in the database DB, for example. Accordingly, classification accuracy of the constructed rule-type classifier for the GUI in FIG. 14 can be checked using the pieces of inspection data accumulated in the database DB as teaching data. In this case, for example, a directory storing teaching data for each group is designated in a directory column 14-2. When a classification accuracy calculation execution button 14-3 is pushed, teaching data in the designated directory is finely classified by the rule-type classifier. Thereafter, classification accuracy (e.g., percentage) is displayed in a result display column 14-4 on the basis of true-false results of classification for each piece of teaching data. An example of calculation of classification accuracy will be described later. In a case where classification accuracy does not reach a desired value, determination conditions, classes, and the like are adjusted, and then classification accuracy is calculated again. These steps are repeated as necessary to obtain classification accuracy exceeding the desired value. When classification conditions are finalized, these classification conditions are stored by operating a not-illustrated storing button or the like.

Note that the way for setting classification conditions of the rule-type classification method is not limited to the manual operation described above, and may be machine learning. For example, a place for storing teaching data is designated in the directory column 14-2, and desired classification accuracy is input to an accuracy input column (not illustrated). When a rule-type classifier construction execution button (not illustrated) is pushed, the signal processing device 300, for example, learns a relation between features of the teaching data in the designated storing place and classification results, and displays classification conditions which meet desired classification accuracy or achieve the maximum classification accuracy in the classification condition column 14-1. Classification accuracy of the displayed classification conditions can be checked or adjusted by using the classification accuracy calculation execution button 14-3 as in the above case. Adjustment of the classification conditions may be achieved by either a manual operation or machine learning as described above.

### —Class Setting—

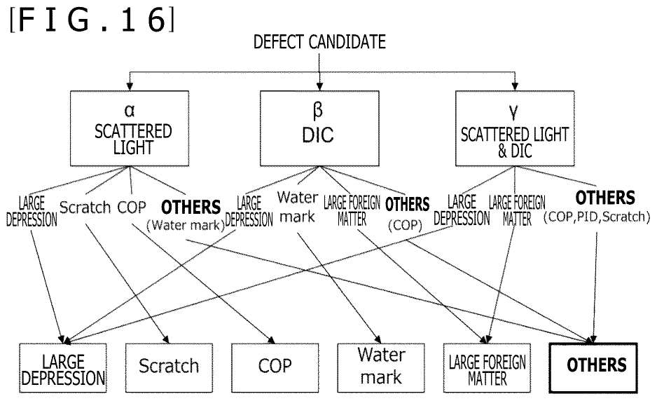

FIG. 15 is a diagram illustrating an example of a GUI for setting classes for each of the groups α, β, and γ. The GUI in FIG. 15 displays icons 15-1 in line for representing classes. Desired classes are selected from the foregoing icons 15-1, and set in a class column 15-2 for each of the groups α, β, and γ. Settings in the class column 15-2 are reflected in the class condition column 14-1 in FIG. 14. Alternatively, the GUI in FIG. 14 can also function as the GUI illustrated in FIG. 15. In this case, the class condition column 14-1 in FIG. 14 corresponds to the class column 15-2. The classes may be set by dragging and dropping the icons 15-1 corresponding to the desired classes into the class column 15-2 in the manner described above, or by machine learning to improve classification accuracy.

The present embodiment is characterized in that a class representing a defect type of “others” for classification collectively including defect types other than defect types designated as detection targets is included in choices of a plurality of the selectable classes. For example, in the case of the group β, clear classification is desired as detection targets for such defect types as a large depression, a low-step defect, and a watermark. However, clear classification is not necessarily required for other defect types. For example, classes for such defect types as defect types not originally required to be classified in an inspection step, defect types infrequently classified and hence not required to be classified, and defect types having features similar to features of other defect types and difficult to clearly classify, to possibly uselessly lower classification accuracy when set as independent classes can each be defined as a defect type of “others” to sum up the classes.

Moreover, after completion of the setting of the classes in the class column 15-2 and the setting of the rule-type classifier in the manner described above, teaching data can be inspected for calculation of classification accuracy as described with reference to FIG. 14. According to the GUI in FIG. 15, classification frequency 15-3 can be checked for each of the classes set in the class column 15-2 for each of the groups α, β, and γ after inspection of the teaching data. When any one of the classes is designated by clicking this class or overlapping a pointer on this class in the class column 15-2, the class frequency 15-3 is displayed. According to the example in FIG. 15, class classification using teaching data is attempted for the defect type of PID set for the group γ. As a result, it is displayed that yy defects (z %) are contained in xx defects recorded in the designated directory. When the number of classes is more than necessary, a probability of erroneous classification increases. Accordingly, classification frequency of each class is checked in the manner described above, and classes exhibiting classification frequency lower than a predetermined value are integrated into the defect type of “others” to reduce classes. As a result, classification accuracy increases.

FIG. 16 is a diagram illustrating a state where the number of classes is reduced by setting the class of the defect type of others in comparison with FIG. 12. According to the example in FIG. 16, the defect type of watermark is replaced with the class of others for the group α, the defect type of COP is replaced with the class of others for the group β, and the defect types of COP, PID, and scratch are replaced with the class of others for the group γ. The foregoing defect types integrated into the class of others in the respective groups are merged into the class of “others” in final inspection data. It is obvious from comparison with the example in FIG. 12 that the number of the classes is reduced in the example of FIG. 16.

### —Different Example of Class Classification—

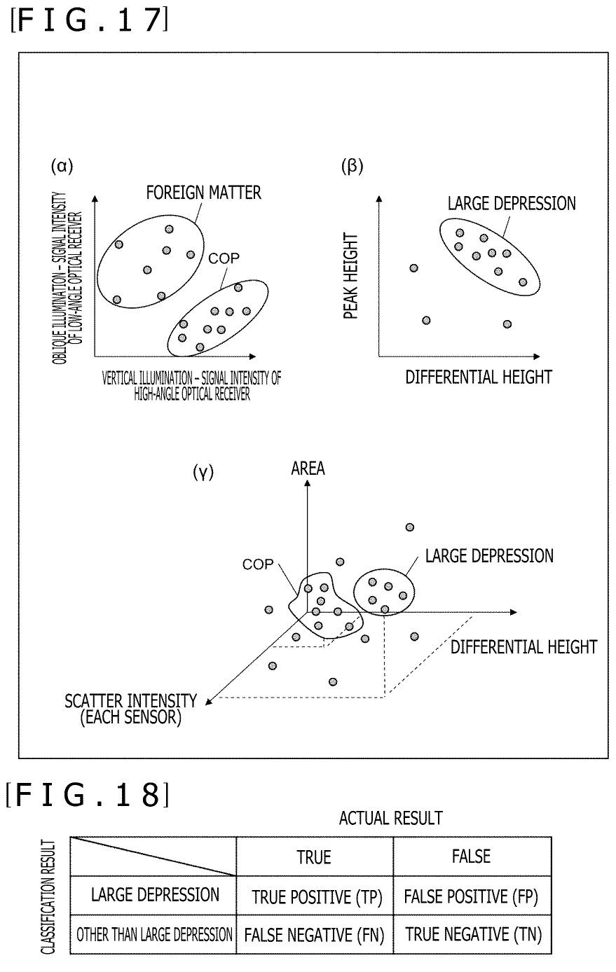

FIG. 17 is a conceptual diagram illustrating an example of machine learning applied to class classification for each of the groups α, β, and γ instead of the rule-type classification logic. While FIG. 17 illustrates classification based on features, determination of identical defect types may be made by image recognition using machine learning for fine classification. For example, the signal processing device 300 may have a machine learning function, and constitute a teaching classifier applied to class classification for each group. For example, a Gaussian Mixture Model may be employed for calculation of the teaching classifier. In this case, the defect distribution is expressed as overlap between a plurality of regular distributions, and defects contained in the respective regular distribution regions are classified into different defect types. Alternatively, a Support Vector Machine, a Neural Network, and other known classifiers may be used. The signal processing device 300 examines a level or upper and lower limits of an influence of features obtained by scattered light inspection and differential interference inspection on classification accuracy for each of the defect types. For example, the signal processing device 300 reads inspection data as teaching data from a designated directory corresponding to the group γ, learns a relation between features of the respective piece of teaching data and defect types, and extracts features having a large influence on class classification of defect candidates grouped into the group γ. FIG. 17(α) illustrates an example of extraction of signal intensity detected by a high-angle optical receiver under a vertical illumination condition and signal intensity detected by a low-angle optical receiver under an oblique illumination condition. FIG. 17(β) illustrates an example of extraction of a differential height and a peak height. FIG. 17(γ) illustrates an example of extraction of a differential height, a defect area, and a scatter signal intensity for each sensor. A teaching classifier for classifying defect candidates is learned for each of the groups in a feature space specified by the extracted features. The classifier for each of the groups α and β can be defined by a smaller number of features than the classifier for the group γ. The number of features in each of the groups α and β is smaller than the number of features in the group γ at the time of rough classification. Accordingly, extraction of features by machine learning can efficiently be carried out. Moreover, the number of features used for fine classification of roughly classified results can be equalized for each of the groups α, β, and γ. Accordingly, learning can be processed by machine learning in the same dimension for all of the teaching classifiers. For example, FIG. 17(γ) indicates a determination boundary of each of the COP and the large depression. In a case where a feature vector of a certain defect candidate is contained in the determination boundary of the COP in the feature space in FIG. 17(γ), this defect candidate is classified into the COP. A teaching classifier is set for each of the groups α and β in a similar manner, and can be employed for class classification.

Furthermore, along with subsequent execution of defect inspection and update of inspection data in a designated directory (including not only addition of data but also deletion of data), for example, the signal processing device 300 may be configured to execute the foregoing machine learning automatically or sequentially and automatically according to an operation by a user and at predetermined time intervals, and update the classification determination boundaries within the feature space.

### —Classification Accuracy Index—

FIG. 18 is an explanatory diagram of classification accuracy. FIG. 18 is a table which indicates four cases, i.e., cases where a defect candidate classified into a large depression actually is a large depression and is not a large depression and cases where a defect candidate not classified into a large depression is a large depression and actually is not a large depression. It is assumed in FIG. 18 that the case of the defect candidate classified into a large depression and actually corresponding to a large depression is true positive (TP: True Positive) and that the case of the defect candidate classified into a large depression but actually corresponding to a defect other than a large depression is false positive (FP: False Positive). It is further assumed that the case of the defect candidate classified into a defect other than a large depression but actually corresponding to a large depression is false negative (FN: False Negative) and that the case of the defect candidate classified into a defect other than a large depression and actually corresponding to a defect other than a large depression is true negative (TN: True Negative). The optotype of classification accuracy described above with reference to FIG. 14 can be set using the foregoing four values. For example, an F value (=2×precision×recall (precision+recall)), which is a harmonic mean of a precision rate (precision) (=TP/(TP+FP)) and a recall rate (recall) (=TP/(TP+FN)), can be designated as an index of classification accuracy.

### —Generation of Teaching Data—

FIG. 19 is an explanatory diagram of an example which provides a classification result of a different group as teaching data to compensate for insufficiency of teaching data in class classification for each of the groups α, β, and γ. For example, the number of defect candidates in the group γ detected by both scattered light inspection and differential interference inspection is likely to be smaller than the number of defect candidates in each of the other groups α and β. This tendency may lead to insufficiency of teaching data in the group γ. Accordingly, for constructing a classification algorithm, in a case where each of the groups α, β, and γ includes a class of a large depression, for example, teaching data classified into the class of the large depression as classification results of teaching data in the groups α and β is provided as data for compensating for teaching data associated with classification of the large depression in the group γ. In this manner, teaching data of a common class is provided from the other groups as teaching data for compensating for insufficiency of teaching data to acquire sufficient classification accuracy.

For example, the compensation for teaching data described with reference to FIG. 19 may be automatically executed as a function of the signal processing device 300. For example, for classification results of classes of each of the groups (classified defect candidates), a predetermined determination value is set beforehand for the number of pieces of data, or a proportion of the number of pieces of data in the total number of pieces of teaching data of the corresponding group. This determination value may be set individually for each of the classes in the respective groups, or may be uniformly set. In addition, the signal processing device 300 is programmed to compare the number or the proportion of the classification results with the determination value for each of the classes at the time of construction of a classification algorithm. In a case where the number or the proportion of defect candidates classified into one of the classes in one of the groups does not reach the determination value, for example, the signal processing device 300 provides defect candidates classified into the corresponding class in one of the different groups as teaching data compensating for the data of the one group, and then again executes construction of the classification algorithm.

### —Display of Inspection Data—

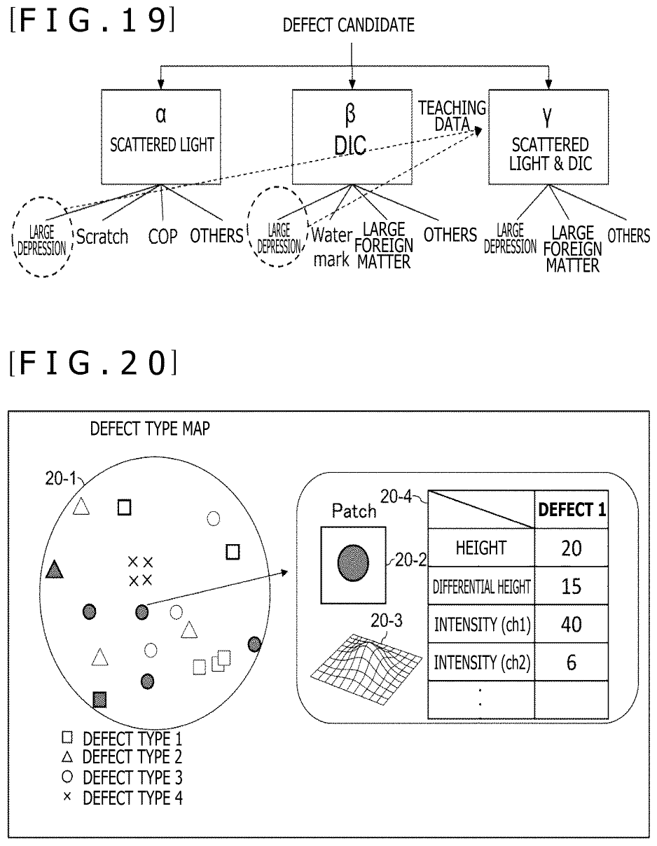

FIG. 20 is a diagram illustrating one example of a GUI which displays a defect type map obtained by defect classification and detailed data obtained for each of defect candidates. A defect type can be identified for each of defect candidates by the foregoing classification, and displayed as a defect type map on a wafer map 20-1 in the GUI in FIG. 20. While this figure indicates a state where all classified defect types are displayed, defects of only one or a plurality of specific types selected as desired may be displayed. This manner of display allows one to examine a position where a defect of a specific type is easily produced on the wafer map 20-1, for example. Moreover, one defect candidate on the wafer map 20-1 may be selected to display a two-dimensional patch image 20-2, a 3D image 20-3, and a list of features 20-4 of the selected defect candidate. The signal processing device 300 can form and output the 3D image 20-3 which reproduces a size and a height, a 3D shape, and the like of the defect, on the basis of features associated with scattered light intensity distribution obtained by the first inspection system 100 and features of a differential height, a sample surface height, and a defect area obtained by the second inspection system 200.

### —Offline Inspection—

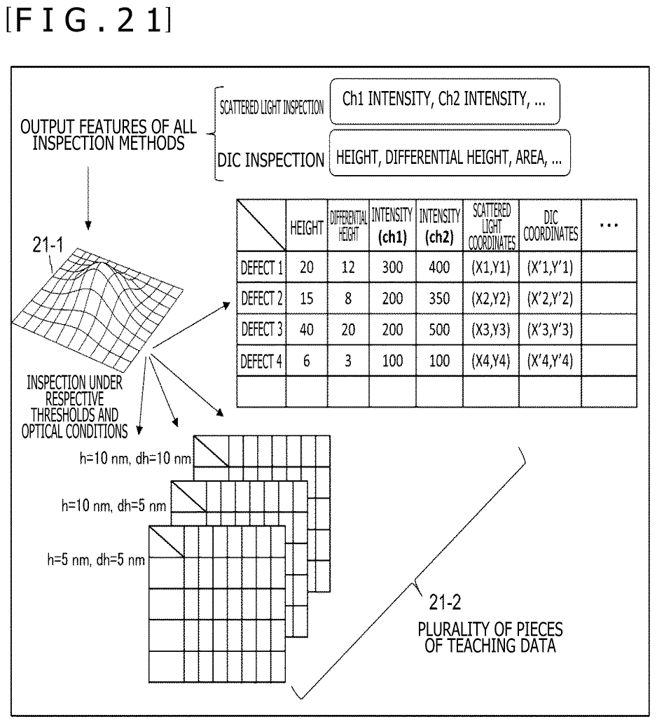

FIG. 21 is an explanatory diagram of offline reinspection. The number of pieces of teaching data can be raised by storing features detected by the first inspection system 100 and the second inspection system 200 and 3D data of defects generated from these features in the database DB or other storage devices as teaching data, and reinspecting these pieces of teaching data under different conditions at a later time. More detailed defect information can be obtained by using a plurality of inspection methods. All the pieces of defect information may be combined and stored as 3D shape data 21-1. For example, a plurality of pieces of teaching data 21-2 can be further obtained from the 3D shape data 21-1 associated with the 3D image 20-3 by reinspecting the 3D shape data 21-1 offline on the basis of different thresholds or under different optical conditions. The 3D shape data 21-1 requires a large storage capacity. Accordingly, when data size reduction is desired, it is preferable to carry out appropriate steps such as cutout and storage of 1 mm square feature data around a defect together with coordinate data.

### Advantageous Effects

(1)

According to the present embodiment, defect candidates are extracted from detection signals of the first inspection system 100 and the second inspection system 200 with use of a high sensitivity threshold set to a value lower than a setting for defect determination so as to extract a large number of defect candidates. In this manner, the largest possible number of defect candidates detected by both the first inspection system 100 and the second inspection system 200 are obtained. Thereafter, coordinates of the defect candidates detected by each of the first inspection system 100 and the second inspection system 200 are checked for comparison. The defect candidates close to each other in view of coordinates are regarded as defect candidates detected by both of the inspection systems, while the defect candidates around which other defect candidates are absent are regarded as defect candidates detected by only one of the inspection systems. In this manner, defect candidates are first roughly grouped into the groups α, β, and γ described above. At this time, a large number of defect candidates, including misinformation, still remain after filtering to which the high sensitivity threshold is applied. Accordingly, a large number of defect candidates can be classified into the group γ as well.

After the large number of extracted defect candidates, including misinformation, are roughly grouped using the inspection methods in this manner, defect types are classified into classes on the basis of individual features of the defect candidates for each of the groups. This manner of classification of the defect candidates achieved by the foregoing procedures allows both of the inspection systems to obtain a large number of pieces of detailed feature data even for defects originally detectable by only either one of the inspection systems. Moreover, exclusion of defect candidates which should originally be treated as classification targets is reduced by use of the high sensitivity threshold lower than a value for removing misinformation and discriminating defects, and feature data of each of the defect candidates is appropriately evaluated for each of the groups. This manner of processing can contribute to reduction of erroneous classification.

According to the present embodiment, therefore, improvement of classification accuracy of defects is achievable even by use of a combination of a plurality of inspection techniques adopting different methods.

(2)

If defect types are classified after removal of misinformation from detection signals of the first inspection system 100 and the second inspection system 200 with use of a threshold, defect candidates separable into the groups α, β, and γ in the present embodiment are filtered with use of a uniform threshold. In this case, there is still room for improvement for optimization of processing for detection signals, and even defect candidates corresponding to targets of classification processing may also be removed.

In contrast, according to the present embodiment, the low sensitivity threshold for removing misinformation from defect candidates classified into classes for each of the groups can be set not uniformly but individually to an appropriate value for each of the groups α, β, and γ, unlike the high sensitivity threshold for extracting a large number of defect candidates grouped into the groups α, β, and γ. Accordingly, this setting is more advantageous for appropriately processing detection signals, and also prevents excessive removal of defect candidates that should be targets of classification processing as described above.

(3)

When an identical class is included in the different groups α, β, and γ, defect inspection data included in the different groups but classified into the same class is integrated and output as defect inspection data in an identical class so as to reduce complication of inspection results.

(4)

As described above, each of the groups α, β, and γ may include a class of a defect type of “others” collectively including defect types other than defect types corresponding to detection targets. For example, if classes are individually set for defect types exhibiting similar characteristics, erroneous classification may increase for these defect types. In this case, two defect types one or both of which are infrequently classified and produce a disadvantage of a low classification accuracy rate when treated as individual classes rather than an advantage of identification of defect types are determined individually for each of the groups and integrated into the class of the defect type of “others.” In this manner, the number of classes is reduced to a necessary and sufficient number, and therefore classification accuracy of defect candidates further improves.

(5)

For class classification of defect candidates for each group, a teaching classifier can be constructed for each group by machine learning of teaching data (e.g., previous inspection data) provided for each group. More accurate classification of defect candidates is achievable by utilization of machine learning in this manner. Moreover, the teaching classifier can be sequentially updated to a more accurate classifier by further repeating machine learning for features of pieces of inspection data accumulated in the future. Accordingly, accuracy of class classification is expected to improve in association with accumulation of inspection data.

(6)

Meanwhile, as described above, class classification of defect candidates for each group may be executed on the basis of a class classification algorithm individually set for each group beforehand. This setting of the classification algorithm can increase flexibility of operation of the defect inspection device, such as identification of an important defect to which a user or the like pays particular attention with use of an algorithm focused on this defect.

(7)

Moreover, classification accuracy can be calculated and output by application of the set classification algorithm to classification of teaching data. Accordingly, the user or the like can check appropriateness and a necessity of adjustment of the classification algorithm.

(8)

When the number or the proportion of defect candidates classified from teaching data for each class by use of the classification algorithm does not reach a determination value in a certain class at the time of construction of the classification algorithms, defect candidates classified into the corresponding class are provided from a different group to compensate for the teaching data of the group for which the class insufficient in the number or proportion has been set.

In grouping defect candidates by detection methods as in the present embodiment, insufficiency in the number of pieces of teaching data may occur in some groups. For example, in a case where the number of pieces teaching data classified into a large depression is insufficient in the group γ, information associated with defects classified into the large depression in each of the groups α and β can be utilized as teaching data for the group γ at the time of teaching classification of the large depression in the group γ according to the present embodiment. As described above, in a case where teaching data is insufficient in any one of the groups, data of a different group is provided to increase the teaching data and compensate for insufficiency in the teaching data. In this manner, accuracy of classification algorithm construction and also accuracy of defect classification can be raised.

(9)

According to the embodiment described above, the first inspection system 100 is a scattered light inspection system, while the second inspection system 200 is a differential interference inspection system. Features associated with a schematic shape of a defect candidate can be obtained by the scattered light inspection, while features associated with a height, a size, and an area of a defect candidate can be obtained by the differential interference inspection. Accordingly, a 3D image of a defect can be formed and output on the basis of these features. In this manner, a state of a defect is visually recognizable with ease.

Furthermore, early improvement of inspection accuracy by an increase in teaching data is expected to be achieved by carrying out offline inspection of 3D data of a defect thus obtained, under different optical conditions and various thresholds at a later time, and adding these offline inspection data to teaching data.

### ADDITIONAL REMARKS

While described has been the example where the defect inspection device including the first inspection system 100 and the second inspection system 200 processes detection signals acquired by the first method and the second method, the defect inspection device is not required to have both the first inspection system 100 and the second inspection system 200 in view of a defect inspection method. For example, essential advantageous effects similar to those of the embodiment described above can be offered by acquiring defect detection signals for an identical sample separately from a first defect inspection device acquiring defect detection signals by the first method and a second defect inspection device acquiring defect detection signals by the second method, and then processing these detection signals in a manner similar to the manner of the embodiment described above. In this case, a device for processing the detection signals is not necessarily limited to a defect inspection device constituting various optical systems, and may be an independent processing device including a single computer or a plurality of computers connected to each other via a network.

In addition, as described in the embodiment, the defect inspection method noted above can be implemented by computer processing. Accordingly, the defect inspection device according to the present invention can be implemented by adding a processing device (corresponding to the signal processing device 300) including a program of the defect inspection method described above to an existing defect inspection device equipped with the first inspection system 100 and the second inspection system 200. Alternatively, the defect inspection device according to the present invention can be implemented by incorporating the program of the defect inspection method described above into the signal processing device 300 included in the existing defect processing device equipped with the first inspection system 100 and the second inspection system 200.

Furthermore, while described above has been the defect inspection device including two types of inspection systems, i.e., the first inspection system 100 and the second inspection system 200, the present invention is also applicable to a defect inspection device including three or more types of inspection systems. In this case, applicable is such an example which divides defect candidates into a group of defect candidates detected by only some (one or a plurality) of inspection systems and a group of defect candidates detected by all inspection systems, and classifies the defect candidates into classes in a manner similar to the manner of the embodiment described above for each of the groups.

### DESCRIPTION OF REFERENCE SYMBOLS

1: Sample
12-2: Class
12-3: Defect inspection data
100: First inspection system
200: Second inspection system
300: Signal processing device
K: Stage
α: First group
β: Second group
γ: Third group

1. A defect inspection device comprising:
a stage that moves while carrying a sample;
a first inspection system that applies illumination light to the sample and detects light from the sample by a first method;
a second inspection system that applies illumination light to the sample and detects light from the sample by a second method different from the first method; and
a signal processing device that processes detection signals output from the first inspection system and the second inspection system,
wherein the signal processing device
compares each of the detection signals of the first inspection system and the detection signals of the second inspection system with a high sensitivity threshold defined for detection including misinformation, to detect defect candidates,
checks for comparison between coordinates of the defect candidates detected by the first inspection system and coordinates of the defect candidates detected by the second inspection system to group the defect candidates into a first group including the defect candidates detected by only the first inspection system, a second group including the defect candidates detected by only the second inspection system, and a third group including the defect candidates detected by both the first inspection system and the second inspection system, and
individually classifies the defect candidates into at least one class according to defect types for each of the first group, the second group, and the third group.

2. The defect inspection device according to claim 1, wherein the signal processing device compares the defect candidates classified into the at least one class with a low sensitivity threshold set to a value higher than the high sensitivity threshold for each of the groups, and outputs defect inspection data from which the misinformation has been filtered out.

3. The defect inspection device according to claim 2, wherein the signal processing device integrates pieces of the defect inspection data classified into the same class but included in the different groups, into defect inspection data in an identical class, and outputs the integrated defect inspection data.

4. The defect inspection device according to claim 1, wherein the at least one class includes a class of a defect type of others as a class collectively including defect types other than a defect type corresponding to a detection target.

5. The defect inspection device according to claim 1, wherein
the signal processing device
sets a feature set provided for each of the groups and used for classification of the defect candidates, and learns, by using the feature set for each of the groups, a classifier that classifies the defect candidates grouped into the groups, and
classifies, by using a result of the learning for each of the groups, the defect candidates grouped into the groups.

6. The defect inspection device according to claim 5, wherein
the signal processing device
classifies teaching data for each of the classes by using the classifier, and compares a number or a proportion of the defect candidates classified into each of the classes with a determination value, and,
in a case where the number or the proportion of the defect candidates classified into one class of one group in the groups does not reach the determination value, provides the defect candidates classified into the corresponding class in a different group of the groups for the one group to compensate for teaching data in the one group.

7. The defect inspection device according to claim 1, wherein the signal processing device classifies the defect candidates for each of the groups on a basis of a classification algorithm for classifying the classes and individually set for each of the groups.

8. The defect inspection device according to claim 7, wherein the signal processing device
executes class classification of teaching data for each of the groups by using the classification algorithm, and
calculates and outputs classification accuracy of the classification algorithm on a basis of a result of the class classification of the teaching data.

9. The defect inspection device according to claim 8, wherein
the signal processing device
classifies the teaching data for each of the classes by using the classification algorithm, and compares a number or a proportion of the defect candidates classified into each of the classes with a determination value, and,
in a case where the number or the proportion of the defect candidates classified into one class of one group in the groups does not reach the determination value, provides the defect candidates classified into the corresponding class in a different group of the groups for the one group to compensate for the teaching data in the one group.

10. The defect inspection device according to claim 1, wherein the first inspection system and the second inspection system are a scattered light inspection system and a differential interference inspection system, respectively.

11. The defect inspection device according to claim 10, wherein the signal processing device forms and outputs a 3D image of a defect on a basis of features obtained by the first inspection system and the second inspection system.

12. The defect inspection device according to claim 11, wherein the signal processing device generates teaching data by reinspecting data of the 3D image under a different condition.

13. A processing device that is a signal processing device configured to process detection signals output by a first inspection system that applies illumination light to a sample and detects light from the sample by a first method and detection signals output by a second inspection system that applies illumination light to the sample and detects light from the sample by a second method different from the first method,
wherein the processing device
compares each of the detection signals of the first inspection system and the detection signals of the second inspection system with a high sensitivity threshold defined for detection including misinformation, to detect defect candidates,
checks for comparison between coordinates of the defect candidates detected by the first inspection system and coordinates of the defect candidates detected by the second inspection system, to group the defect candidates into a first group including the defect candidates detected by only the first inspection system, a second group including the defect candidates detected by only the second inspection system, and a third group including the defect candidates detected by both the first inspection system and the second inspection system, and
individually classifies the defect candidates into at least one class according to defect types for each of the first group, the second group, and the third group.

14. The processing device according to claim 13, wherein
the processing device inspects teaching data for each of the groups, and compares a number or a proportion of the defect candidates classified into each of the classes with a determination value, and,
in a case where the number or the proportion of the defect candidates classified into one class of one group in the groups does not reach the determination value, the processing device provides the defect candidates classified into the corresponding class in a different group of the groups for the one group to compensate for teaching data in the one group.

15. A defect inspection method comprising:
moving a stage carrying a sample;
applying illumination light to the sample and detecting light from the sample by a first method with use of a first inspection system;
applying illumination light to the sample and detecting light from the sample by a second method different from the first method with use of a second inspection system;
comparing each of the detection signals of the first inspection system and the detection signals of the second inspection system with a high sensitivity threshold defined for detection including misinformation, to detect defect candidates;
checking for comparison between coordinates of the defect candidates detected by the first inspection system and coordinates of the defect candidates detected by the second inspection system, and grouping the defect candidates into a first group including the defect candidates detected by only the first inspection system, a second group including the defect candidates detected by only the second inspection system, and a third group including the defect candidates detected by both the first inspection system and the second inspection system;
individually classifying the defect candidates into at least one class according to defect types for each of the first group, the second group, and the third group;
comparing the defect candidates classified into the at least one class for each of the groups with a low sensitivity threshold set to a value higher than the high sensitivity threshold, and outputting defect inspection data from which the misinformation has been filtered out.
